(19) United States
(12) Patent Application Publication
(10) Pub. No.: US 2025/0268082 A1
(43) Pub. Date: Aug. 21, 2025

(54) DISPLAY DEVICE

(71) Applicant: SAMSUNG DISPLAY CO., LTD., YONGIN-SI, GYEONGGI-DO (KR)

(72) Inventors: Hyang Yul KIM, Yongin-si, Gyeonggi-do (KR); Hee Seong JEONG, Yongin-si, Gyeonggi-do (KR)

(21) Appl. No.: 18/909,201

(22) Filed: Oct. 8, 2024

(30) Foreign Application Priority Data
Feb. 15, 2024 (KR) 10-2024-0021710

(51) Int. Cl. H10K 59/80

(52) U.S. Cl. CPC H10K 59/8792; H10K 59/8793

(57) ABSTRACT

A display device includes a display panel. A light control film is disposed above the display panel. The light control film includes a light control layer including a light transmission pattern and a light blocking pattern disposed alternately with each other in a horizontal direction. A base film layer is disposed on the light control layer. A polarizing film is disposed above the light control film. The polarizing film includes a phase retardation layer, a first protective layer, a polarizing layer, and a second protective layer.

### CROSS-REFERENCE TO RELATED APPLICATION

This application claims priority under 35 U.S.C. § 119 to Korean Patent Application No. 10-2024-0021710, filed on Feb. 15, 2024 in the Korean Intellectual Property Office, the disclosure of which is incorporated by reference in its entirety herein.

### 1. TECHNICAL FIELD

The present disclosure relates to a display device.

### 2. DISCUSSION OF RELATED ART

The demand for display devices for displaying an image which are provided in various forms has increased along with the development of the information society. The display device may be a flat panel display, such as a liquid crystal display, a field emission display, or a light emitting display panel. The light emitting display device may include an organic light emitting diode display device including an organic light emitting diode element as a light emitting element or a light emitting diode display device including an inorganic light emitting diode element such as a light emitting diode (LED) as a light emitting element.

When the display device is applied to a vehicle display device, an image displayed on the vehicle display device disposed in front of a driver or passenger is reflected on a windshield at night and may interfere with the driver's driving. Therefore, it is necessary to control a viewing angle of the image displayed on the vehicle display device. In addition, for purpose of protecting privacy, it is necessary to control the viewing angle of the images displayed on the vehicle display device to prevent the images disposed in front of the driver from being provided to passengers and to prevent images displayed in front of passengers from being provided to the driver.

### SUMMARY

Aspects of embodiments of the present disclosure provide a display device capable of controlling a viewing angle.

Aspects of embodiments of the present disclosure also provide a display device capable of minimizing yellowing.

Aspects of embodiments of the present disclosure also provide a display device capable of minimizing external light reflection.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an embodiment of the present disclosure, a display device includes a display panel. A light control film is disposed above the display panel. The light control film includes a light control layer including a light transmission pattern and a light blocking pattern disposed alternately with each other in a horizontal direction. A base film layer is disposed on the light control layer. A polarizing film is disposed above the light control film. The polarizing film includes a phase retardation layer, a first protective layer, a polarizing layer, and a second protective layer.

In an embodiment, the light control film is disposed directly between the display panel and the polarizing film.

In an embodiment, at least one of the first protective layer and the second protective layer is disposed on an opposite side of the display panel with respect to the light control film.

In an embodiment, an ultraviolet transmittance of the base film layer is greater than an ultraviolet transmittance of the first protective layer and the second protective layer.

In an embodiment, the first protective layer and the second protective layer include an ultraviolet absorber.

In an embodiment, a birefringence of the light control film is less than or equal to about 0.03.

In an embodiment, an SCI reflectance of the display device is less than or equal to about 5.5%.

In an embodiment, the base film layer includes tri-acetyl cellulous (TAC).

In an embodiment, the first protective layer and the second protective layer include tri-acetyl cellulous (TAC).

According to an embodiment of the present disclosure, a display device includes a display panel. A light control film is disposed above the display panel. The light control film includes a light control layer including a light transmission pattern and a light blocking pattern disposed alternately with each other in a horizontal direction. A base film layer is disposed on the light control layer. A polarizing film is disposed above the light control film. The polarizing film includes a phase adjustment layer and a polarization protective layer disposed on the phase adjustment layer.

In an embodiment, the light control film is disposed directly between the display panel and the polarizing film.

In an embodiment, the polarization protective layer is disposed on an opposite side of the display panel with respect to the light control film.

In an embodiment, an ultraviolet transmittance of the base film layer is greater than an ultraviolet transmittance of the polarization protective layer.

In an embodiment, the polarization protective layer includes an ultraviolet absorber.

In an embodiment, a birefringence of the light control film is less than or equal to about 0.03.

In an embodiment, an SCI reflectance of the display device is less than or equal to about 5.5%.

In an embodiment, the base film layer includes tri-acetyl cellulous (TAC).

In an embodiment, the polarization protective layer includes tri-acetyl cellulous (TAC).

According to an embodiment of the present disclosure, a display device includes a display panel. A light control film is disposed above the display panel. The light control film includes a light control layer including a light transmission pattern and a light blocking pattern disposed alternately with each other in a horizontal direction. A polarizing film is disposed above the light control film. The polarizing film includes a phase retardation layer, a first protective layer, a polarizing layer, and a second protective layer. The light control layer is in direct contact with the polarizing film. A birefringence of the light control film is less than or equal to about 0.03.

In an embodiment, an SCI reflectance of the display device is less than or equal to about 5.5%.

In the display device according to an embodiment of the present disclosure, the viewing angle may be controlled.

In the display device according to an embodiment of the present disclosure, the yellowing may be minimized.

In the display device according to an embodiment of the present disclosure, the external light reflection may be minimized.

However, the effects of embodiments of the present disclosure are not restricted to the one set forth herein.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is an exploded perspective view illustrating a display device according to an embodiment of the present disclosure;

FIG. 2 is a plan view illustrating a display device according to an embodiment of the present disclosure;

FIG. 3 is an exploded perspective view illustrating a display device according to an embodiment of the present disclosure;

FIG. 4 is a schematic cross-sectional view of the display device taken along line X1-X1′ of FIG. 2 according to an embodiment of the present disclosure;

FIG. 5A is a schematic view of the display device applied to a vehicle according to an embodiment of the present disclosure;

FIG. 5B is a schematic view of the display device applied to a vehicle according to an embodiment of the present disclosure;

FIG. 6 is a cross-sectional view illustrating an example of a display panel according to an embodiment of the present disclosure;

FIG. 7A is a cross-sectional view illustrating a polarizing film according to an embodiment of the present disclosure;

FIG. 7B is a cross-sectional view illustrating a polarizing film according to an embodiment of the present disclosure;

FIG. 8 is a cross-sectional view illustrating a light control film according to an embodiment of the present disclosure;

FIG. 9 is a cross-sectional view illustrating a display device according to an embodiment of the present disclosure;

FIG. 10 is a graph illustrating light transmittance for each wavelength of a base film layer of a light control film according to a first comparative example, a protective layer of a polarizing film according to an embodiment of the present disclosure, and a base film layer of a light control film according to an embodiment of the present disclosure;

FIGS. 11A to 11C are graphs illustrating solar test results of a display device according to a second comparative example;

FIGS. 12A to 12C are graphs illustrating solar test results of a display device according to embodiments of the present disclosure;

FIGS. 13A and 13B are graphs illustrating external light reflectance of a display device according to third to fifth comparative examples and an embodiment of the present disclosure; and

FIG. 14 is a cross-sectional view illustrating a display device according to an embodiment of the present disclosure.

### DETAILED DESCRIPTION OF EMBODIMENTS

The invention will now be described more fully hereinafter with reference to the accompanying drawings, in which non-limiting embodiments of the present disclosure are shown. This invention may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

Hereinafter, embodiments of the present disclosure will be described in detail with reference to the accompanying drawings.

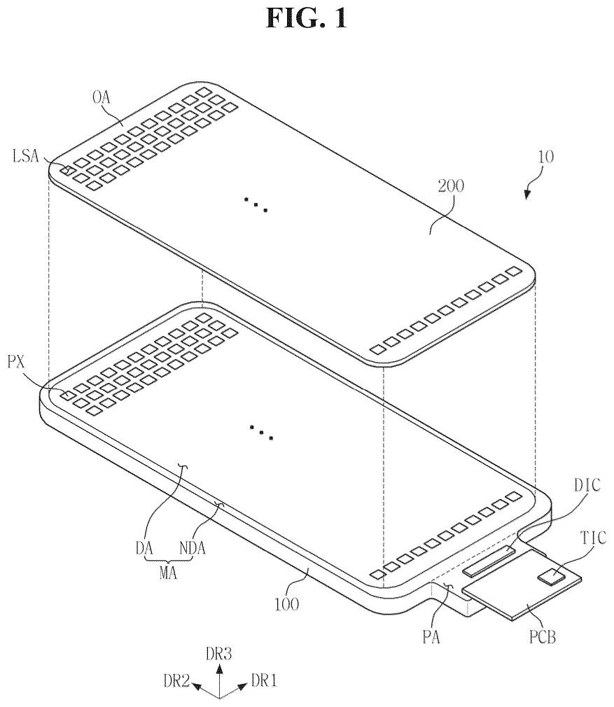

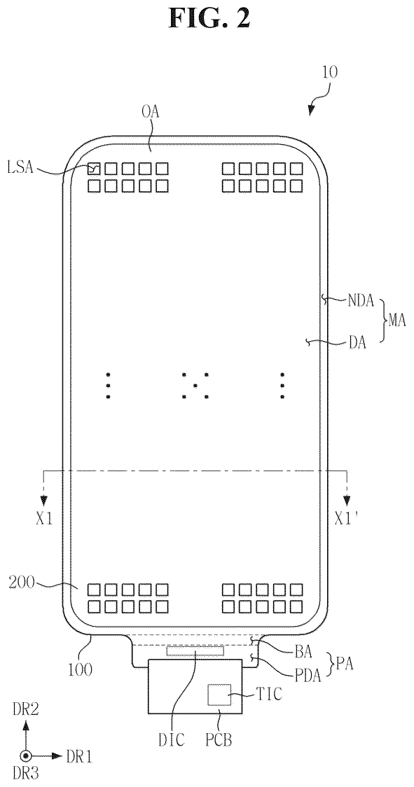

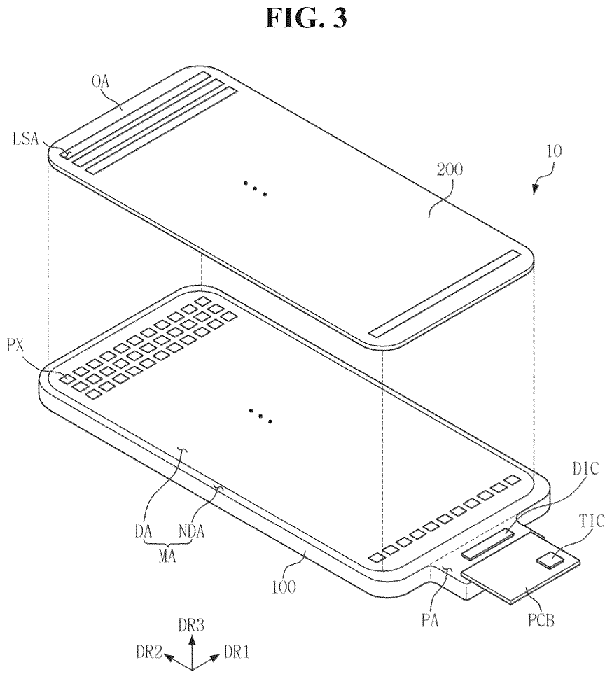

FIG. 1 is an exploded perspective view illustrating a display device according to an embodiment. FIG. 2 is a plan view illustrating a display device according to an embodiment. FIG. 3 is an exploded perspective view illustrating a display device according to an embodiment.

Referring to FIGS. 1 to 3, a display device 10 is a device that displays at least one moving image and or a still image, and may be used as a display screen of each of various products such as vehicles, televisions, laptop computers, monitors, billboards, and Internet of Things (IoT) as well as portable electronic devices such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs).

In some embodiments in which the display device 10 is used as a display screen for a vehicle, the display device 10 may be a vehicle display. The vehicle display may provide users with various service information such as convenience functions, media information, etc., as well as information about vehicle operation information and status information. In an embodiment in which the display device 10 includes an input device such as a touch panel, the user may manipulate various functions such as a driving mode of the vehicle and convenience functions through the display device 10.

In an embodiment, the display device 10 may be any one of an organic light emitting display device, a liquid crystal display device, a plasma display device, a field emission display device, an electrophoretic display device, an electrowetting display device, a quantum dot light emitting display device, and a micro LED display device. Hereinafter, it is mainly described that the display device 10 is the organic light emitting display device. However, embodiments of the present disclosure are not necessarily limited thereto.

The display device 10 according to an embodiment may include a display panel 100, a light control film 200, a display driving circuit DIC, a circuit board PCB, and a touch driving circuit TIC.

The display panel 100 may include a plurality of pixels PX arranged in a first direction DR1 and a second direction DR2. In an embodiment, each of the pixels PX may have a planar shape such as a rectangle, a square, or a rhombus. For example, as illustrated in the drawing, each of the pixels PX may have a planar shape such as a square. However, embodiments of the present disclosure are not necessarily limited thereto and each of the pixels PX may have various shapes such as a polygon, a circle, and an ellipse in plan view.

In the illustrated drawings, the first direction DR1 and the second direction DR2 are each horizontal directions and intersect each other. For example, the first direction DR1 and the second direction DR2 may be orthogonal to each other. In addition, a third direction DR3 may be a vertical direction intersecting the first direction DR1 and the second direction DR2, for example, orthogonal to the first direction DR1 and the second direction DR2. However, embodiments of the present disclosure are not necessarily limited thereto and the first to third directions DR1 to DR3 may cross each other at various different angles. In the present specification, a direction indicated by the first to third directions DR1, DR2, and DR3 in the drawing may be referred to as one side, and an opposite direction may be referred to as the other side, and unless otherwise specified, may include both sides.

In an embodiment, the display panel 100 may include a main area MA and a protruding area PA protruding from one side of the main area MA, such as a lower side in the second direction DR2).

In an embodiment, the main area MA may be formed in a rectangular shape in a plan view having relatively short sides in the first direction DR1 and relatively long sides in the second direction DR2 intersecting the first direction DR1. A corner where the relatively short side in the first direction DR1 and the relatively long side in the second direction DR2 meet may be rounded to have a predetermined curvature or may be formed at a right angle. However, the planar shape of the display device 10 is not necessarily limited to a quadrangular shape, and may be formed in other polygonal, circular, or oval shapes. In an embodiment, the main area MA may be formed to be flat. However, embodiments of the present disclosure are not necessarily limited thereto, and the main area MA may include curved portions formed at left and right ends in some embodiments. In this embodiment, the curved portion may have a constant curvature or a changing curvature.

The main area MA may include a display area DA in which pixels are formed to display an image, and a non-display area NDA which is a peripheral area of the display area DA and may not include pixels.

In addition to pixels, scan lines, data lines, and power lines connected to the pixels may be disposed in the display area DA. In an embodiment in which the main area MA includes the curved portion, the display area DA may be disposed on the curved portion. In this embodiment, the image of the display panel 100 may be viewed even on the curved portion.

The non-display area NDA may be defined as an area from the outside of the display area DA to an edge of the display panel 100 (e.g., in a plan view). In an embodiment, a scan driver for applying scan signals to the scan lines and link lines connecting the data lines and the display driving circuit DIC may be disposed in the non-display area NDA.

The protruding area PA may protrude from one side of the main area MA. For example, the protruding area PA may protrude from a lower side of the main area MA (e.g., in the second direction DR2) as illustrated in FIG. 2. In an embodiment, a length of the protruding area PA in the first direction DR1 may be less than a length of the main area MA in the first direction DR1.

In an embodiment, the protruding area PA may include a bending area BA and a pad area PDA. In this embodiment, the pad area PDA may be disposed on one side of the bending area BA (e.g., in the second direction DR2), and the main area MA may be disposed on the other side of the bending area BA (e.g., in the second direction DR2). For example, the pad area PDA may be disposed on a lower side of the bending area BA (e.g., in the second direction DR2), and the main area MA may be disposed on an upper side of the bending area BA (e.g., in the second direction DR2).

In an embodiment, the display panel 100 may be flexibly formed to be curved, bent, folded, or rolled. Therefore, the display panel 100 may be bent in a thickness direction, such as in a third direction DR3, in the bending area BA. In this embodiment, before the display panel 100 is bent, one surface of the pad area PDA of the display panel 100 faces upward, but after the display panel 100 is bent, one surface of the pad area PDA of the display panel 100 faces downward. As a result, since the pad area PDA is disposed on a lower side of the main area MA, the pad area PDA may overlap the main area MA (e.g., in the third direction DR3).

Pads electrically connected to the display driving circuit DIC and the circuit board PCB may be disposed in the pad area PDA of the display panel 100.

The display driving circuit DIC outputs signals and voltages for driving the display panel 100. For example, the display driving circuit DIC may supply data voltages to the data lines. In addition, the display driving circuit DIC may supply power voltage to the power line and scan control signals to a scan driver. In an embodiment, the display driving circuit DIC may be formed as an integrated circuit (IC) and be attached onto the display panel 100 in the pad area PDA using a chip on glass (COG) method, a chip on plastic (COP) method, or an ultrasonic bonding method. However, embodiments of the present disclosure are not necessarily limited thereto. For example, in an embodiment the display driving circuit DIC may be mounted on the circuit board PCB.

The pads may include display pads electrically connected to the display driving circuit DIC and touch pads electrically connected to the touch lines.

In an embodiment, the circuit board PCB may be attached onto the pads using an anisotropic conductive film. Accordingly, lead lines of the circuit board PCB may be electrically connected to the pads. In an embodiment, the display circuit board PCB may be a flexible film such as a flexible printed circuit board, a printed circuit board, or a chip on film.

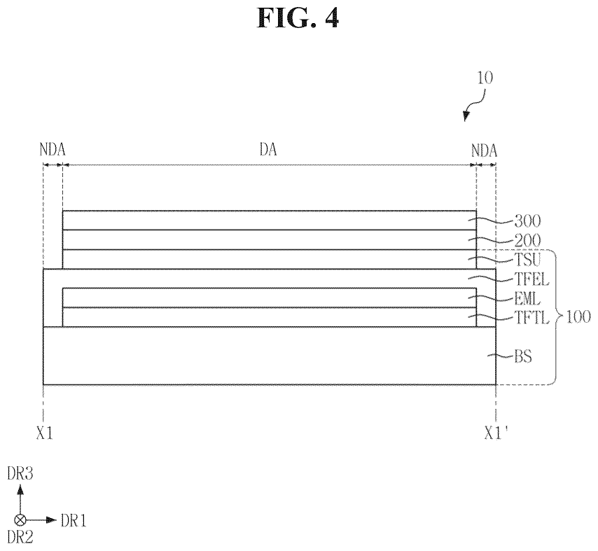

The touch driving circuit TIC may be connected to touch electrodes of a touch sensor layer TSU (see FIG. 4) of the display panel 100. The touch driving circuit TIC applies driving signals to the touch electrodes of the touch sensor layer TSU (see FIG. 4) and measures capacitance values of the touch electrodes. In an embodiment, the driving signal may be a signal having a plurality of driving pulses. The touch driving circuit TIC may not only determine whether a touch is input but also calculate touch coordinates where a touch is input, based on the capacitance values.

The touch driving circuit TIC may be disposed on the circuit board PCB. For example, in an embodiment the touch driving circuit TIC may be formed as an integrated circuit and be disposed directly on the circuit board PCB. However, embodiments of the present disclosure are not necessarily limited thereto.

The light control film 200 may be disposed on the main area MA of the display panel 100. In some embodiments, the light control film 200 may be manufactured separately from the display panel 100 and attached onto the display panel 100. In an embodiment, the light control film 200 may include an adhesive layer to which a release film is attached before being attached to the display panel 100. When the light control film 200 is attached onto the display panel 100, the release film may then be removed, and the display panel 100 and the light control film 200 may be bonded to each other through the adhesive layer.

The light control film 200 may be disposed on the display area DA of the main area MA. The light control film 200 may control a viewing angle of light emitted from the display panel 100.

However, embodiments of the present disclosure are not necessarily limited thereto, and a size of the light control film 200 in a plan view may be greater than a size of the display area DA. In this embodiment, the light control film 200 may overlap (e.g., in the third direction DR3) both the display area DA and the non-display area NDA.

The light control film 200 may include a transmissive area OA and a non-transmissive area LSA.

As illustrated in FIG. 1, the transmissive area OA may surround the non-transmissive areas LSA (e.g., in the first and/or second directions DR1, DR2). However, embodiments of the present disclosure are not necessarily limited thereto, and the non-transmissive area LSA may also surround the transmissive areas OA (e.g., in the first and/or second directions DR1, DR2) in some embodiments. In an embodiment, the transmissive areas OA and the non-transmissive areas LSA may be alternately disposed in the first direction DR1 or alternately disposed in the second direction DR2.

Hereinafter, for convenience of explanation, an embodiment in which the transmissive area OA surrounds the non-transmissive areas LSA will be described as an example.

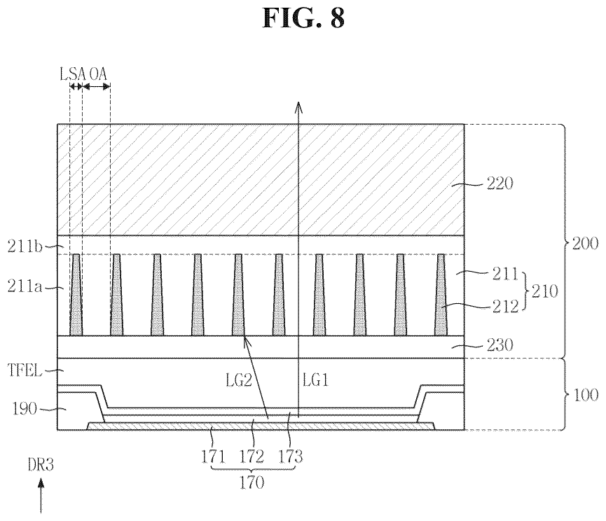

The transmissive area OA may be an area in which a light blocking pattern 212 (see FIG. 8) is not disposed. As illustrated in FIG. 1, the transmissive area OA may surround the non-transmissive areas LSA in a plan view.

In an embodiment, the transmissive area OA may have a quadrangular shape in plan view as illustrated in FIGS. 1 and 2. However embodiments of the present disclosure are not necessarily limited thereto. In some embodiments, the transmissive area OA may have a circular, oval, or polygonal shape in a plan view. In some embodiments, the shape of the transmissive area OA may substantially correspond to the shape of the display panel 100.

The non-transmissive areas LSA may be remaining areas of the light control film 200 excluding the transmissive area OA. The non-transmissive areas LSA may be areas in which the light blocking pattern 212 (see FIG. 8) is disposed.

As illustrated in FIG. 1, the non-transmissive areas LSA may be arranged in the first direction DR1 and the second direction DR2. In an embodiment, as illustrated in FIG. 3, the non-transmissive areas LSA may extend longitudinally in the first direction DR1 and be arranged in the second direction DR2. In an embodiment, the non-transmissive areas LSA may extend longitudinally in the second direction DR2 and be arranged in the first direction DR1.

As illustrated in FIG. 1, when the non-transmissive areas LSA are disposed along the first direction DR1 and the second direction DR2, the viewing angle may be controlled in both the first direction DR1 and the second direction DR2. As illustrated in FIG. 3, when the non-transmissive areas LSA are disposed along the first direction DRI or the second direction DR2, the viewing angle may be controlled in the first direction DR1 or the second direction DR2. For example, the arrangement and shape of the transmissive areas OA may be variously modified depending on the required control direction of the viewing angle.

FIG. 4 is a schematic cross-sectional view of the display device taken along line X1-X1′ of FIG. 2.

Referring to FIG. 4, in an embodiment the display device 10 may include a display panel 100, a light control film 200, and a polarizing film 300.

In an embodiment, the display panel 100 may include a base member BS, a thin film transistor layer TFTL, a light emitting element layer EML, a thin film encapsulation layer TFEL, and a touch sensor layer TSU.

The base member BS may include a substrate. The substrate may be made of an insulating material such as glass, quartz, or a polymer resin. In an embodiment, the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. However, embodiments of the present disclosure are not necessarily limited thereto. Alternatively, the substrate may also include a metal material.

The substrate may be a rigid substrate or may be a flexible substrate that may be bent, folded, and rolled. In an embodiment in which the substrate is the flexible substrate, the substrate may be formed of polyimide PI. However, embodiments of the present disclosure are not necessarily limited thereto.

The thin film transistor layer TFTL may be disposed on the base member BS (e.g., disposed directly thereon in the third direction DR3). In the thin film transistor layer TFTL, scan lines, data lines, power lines, scan control lines, and routing lines connecting the pads and the data lines as well as thin film transistors of each of the pixels may be formed. In an embodiment, each of the thin film transistors may include a gate electrode, a semiconductor layer, a source electrode, and a drain electrode.

In an embodiment, the thin film transistor layer TFTL may be disposed in the display area DA and the non-display area NDA. For example, the thin film transistors of each of the pixels, the scan lines, the data lines, and the power lines of the thin film transistor layer TFTL may be disposed in the display area DA. The scan control lines and link lines of the thin film transistor layer TFTL may be disposed in the non-display area NDA.

The light emitting element layer EML may be disposed on the thin film transistor layer TFTL (e.g., disposed directly thereon in the third direction DR3)). The light emitting element layer EML may include pixels including a first electrode, a light emitting layer, and a second electrode, and a pixel defining film defining the pixels. In an embodiment, the light emitting layer may be an organic light emitting layer including an organic material. In this embodiment, the light emitting layer may include a hole transporting layer, an organic light emitting layer, and an electron transporting layer. When a predetermined voltage is applied to the first electrode and a cathode voltage is applied to the second electrode through the thin film transistor of the thin film transistor layer TFTL, holes and electrons move to the organic light emitting layer through the hole transporting layer and the electron transporting layer, respectively, and are bonded to each other in the organic light emitting layer to emit light. The pixels of the light emitting element layer EML may be disposed in the display area DA.

The thin film encapsulation layer TFEL may be disposed on the light emitting element layer EML (e.g., disposed directly thereon in the third direction DR3). The thin film encapsulation layer TFEL may serve to prevent oxygen or moisture from permeating into the light emitting element layer EML. For example, in an embodiment the thin film encapsulation layer TFEL may include at least one inorganic film. In some embodiments, the inorganic film may be a silicon nitride layer, a silicon oxynitride layer, a silicon oxide layer, a titanium oxide layer, or an aluminum oxide layer. However, embodiments of the present disclosure are not necessarily limited thereto. In addition, the thin film encapsulation layer TFEL may serve to protect the light emitting element layer EML from foreign substances such as dust. For example, in an embodiment the thin film encapsulation layer TFEL may include at least one organic film. In some embodiments, the organic film may be made of an acrylic resin, an epoxy resin, a phenolic resin, a polyamide resin, or a polyimide resin. However, embodiments of the present disclosure are not necessarily limited thereto.

The thin film encapsulation layer TFEL may be disposed in both the display area DA and the non-display area NDA. For example, in an embodiment the thin film encapsulation layer TFEL may be disposed to cover the light emitting element layer EML of the display area DA and the non-display area NDA, and cover the thin film transistor layer TFTL of the non-display area NDA.

The touch sensor layer TSU may be disposed on the thin film encapsulation layer TFEL (e.g., disposed directly thereon in the third direction DR3). In an embodiment in which the touch sensor layer TSU is directly disposed on the thin film encapsulation layer TFEL, the thickness of the display device 10 may be reduced as compared to an embodiment in which a separate touch panel including the touch sensor layer TSU is attached onto the thin film encapsulation layer TFEL.

The touch sensor layer TSU may include touch electrodes for sensing a user's touch in a capacitance method, and touch lines connecting the pads and the touch electrodes. For example, in an embodiment the touch sensor layer TSU may sense a user's touch in a self-capacitance method or a mutual capacitance method.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control film 200 may be disposed on the display panel 100 (e.g., disposed directly thereon in the third direction DR3). In an embodiment, the light control film 200 may be manufactured separately from the display panel 100 and attached onto the display panel 100. The light control film 200 may include an adhesive layer to which a release film is attached before being attached to the display panel 100. When the light control film 200 is attached onto the display panel 100, the release film may be removed, and the display panel 100 and the light control film 200 may be bonded to each other through the adhesive layer.

In an embodiment, the light control film 200 may be disposed to overlap the display area DA. The light control film 200 may serve to absorb or block light that travels beyond a certain angle with respect to the third direction DR3 among the light emitted from the light emitting element layer EML. For example, the light control film 200 may control the viewing angle by limiting the range of angles that the light travels.

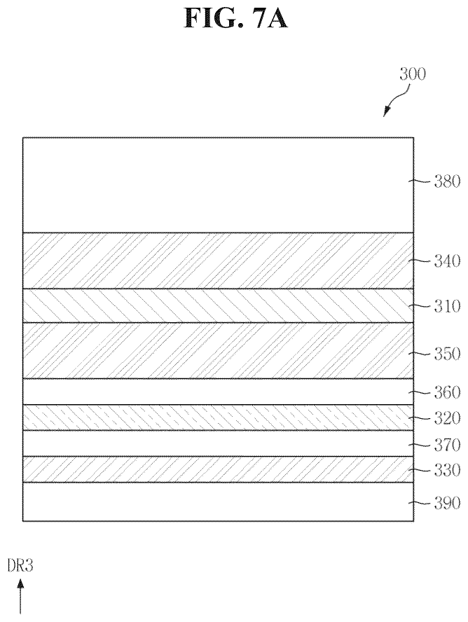

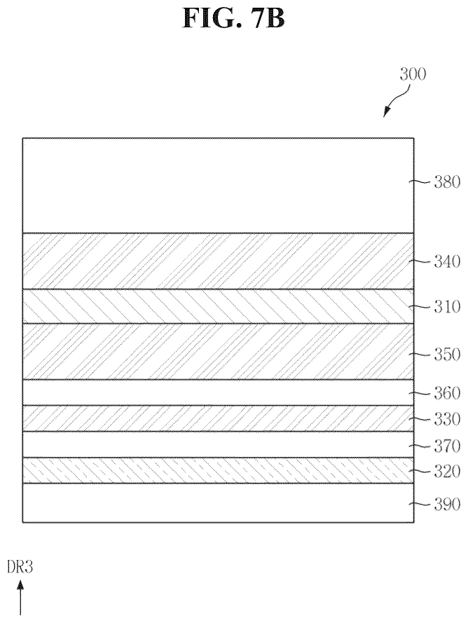

The polarizing film 300 may be disposed on the light control film 200 (e.g., disposed directly thereon in the third direction DR3). The polarizing film 300 may reduce external light reflection. In an embodiment, the polarizing film 300 may include a phase adjusting layer such as a polarizing layer 310 (see FIG. 7A) and a phase retardation layer 320 (see FIG. 7A), and may reduce external light reflection by adjusting a phase of external light incident on the polarizing film 300.

In an embodiment, the display device 10 may further include a cover window. The cover window may be additionally disposed on the polarizing film 300. In this embodiment, the polarizing film 300 and the cover window may be attached by a transparent adhesive member such as a pressure sensitive adhesive film (PSA) or an optically clear adhesive film (OCA).

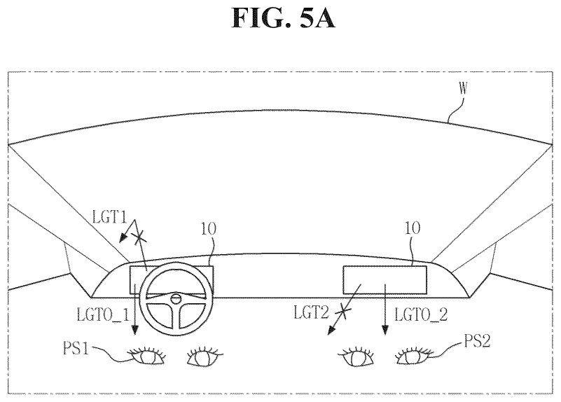

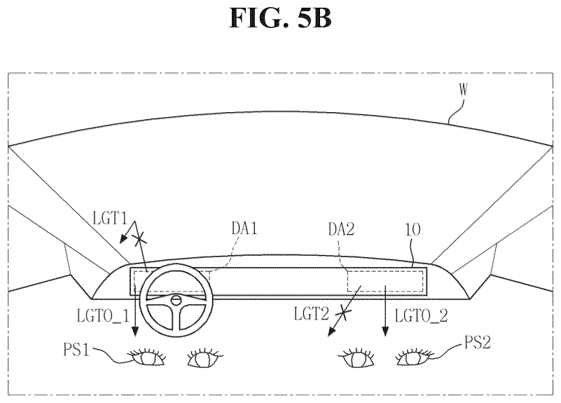

FIG. 5A is a schematic view when the display device is applied to a vehicle according to an embodiment of the present disclosure.

FIG. 5B is a schematic view when the display device is applied to a vehicle according to an embodiment of the present disclosure.

Referring to FIGS. 5A and 5B, the display device 10 according to an embodiment may be, for example, a display device applied to a vehicle. The vehicle may include a body forming an exterior of the vehicle and an interior space defined by the body. The body may include a windshield W that protects a driver PS1 and a passenger PS2 from the outside and provides visibility to the driver PS1. As illustrated in the drawing, the display device 10 may be provided in the interior space.

In some embodiments, the display device 10 may be disposed on a dashboard provided in the interior space. As an example, in an embodiment the display device 10 may be disposed on a dashboard in front of a driver's seat to provide speed information, etc. to the driver PS1, may be disposed on a dashboard in front of a passenger seat to provide entertainment information, etc. to the passenger PS2, and/or may be disposed in the center of the dashboard to provide map information, etc. FIG. 5A illustrates that the display device 10 is disposed on the dashboard in front of the driver's seat and in front of the passenger seat, respectively.

As another example, as illustrated in FIG. 5B, the display device 10 may extend from the dashboard positioned in front of the driver's seat to the dashboard positioned in front of the passenger seat. For example, the display device 10 may be an integrated display connected from the dashboard positioned in front of the driver's seat to the dashboard positioned in front of the passenger seat. In this embodiment, the display device 10 may include a first display area DA1 positioned in front of the driver's seat and a second display area DA2 positioned in front of the passenger seat. In an embodiment, the display device 10 may further include a third display area between the first display area DA1 and the second display area DA2.

Hereinafter, for convenience of explanation, the embodiment of FIG. 5A will be described as an example. However, embodiments of the present disclosure are not necessarily limited to the embodiment of FIG. 5A, and in the integrated display as in the embodiment of FIG. 5B, the first display area DA1 and the second display area DA2 correspond to the display device 10 in front of the driver's seat and the display device 10 in front of the passenger seat, respectively, of FIG. 5A, and the same technical idea may be applied thereto.

The driver PS1 may recognize (e.g., visually recognize) a display screen of the display device 10 through light LGT0_1 emitted from the display device 10 towards the driver PS1. However, some light LGT1 among the light emitted from the display device 10 in front of the driver's seat may be reflected on the surrounding windshield W and provided to the driver PS1. In this case, the image displayed on the windshield W may interfere with the driving of the driver PS1. However, in the display device 10 according to an embodiment of the present disclosure, it is possible to prevent in advance a portion of light LGT1 of the light emitted from the display device 10 in front of the driver's seat from being reflected on the surrounding windshield W and provided to the driver PS1 by adjusting a viewing angle, especially a vertical viewing angle, with respect to a front direction (e.g., the direction facing the driver PS1) of the light emitted from the display device 10.

In an embodiment, the passenger PS2 may recognize (e.g., visually recognize) a display screen of the display device 10 through light LGT0_2 emitted from the display device 10 in front of the passenger seat towards the passenger PS2. However, some light LGT2 of the light emitted from the display device 10 in front of the passenger seat may be provided toward the driver PS1 which may distract the driver PS1 from safely operating the vehicle. However, in the display device 10 according to an embodiment of the present disclosure, it is possible to prevent a portion of the light LGT2 of the light emitted from the display device 10 in front of the passenger seat from being provided to the driver by adjusting the viewing angle, especially the left and right viewing angles, with respect to the front direction (e.g., the direction facing the passenger PS2) of the light emitted from the display device 10.

It is illustrated in the drawing that the display device 10 in front of the driver's seat adjusts the vertical viewing angle, and the display device 10 in front of the passenger seat adjusts the left and right viewing angle. However, embodiments of the present disclosure are not necessarily limited thereto. As an example, the display device 10 in front of the driver's seat may also adjust the right and left viewing angle, and the display device 10 in front of the passenger seat may also adjust the vertical viewing angle. As another example, the display device 10 in front of the driver's seat and the display device 10 in front of the passenger seat may also adjust both the vertical viewing angle and the left and right viewing angle, respectively.

The viewing angle may be adjusted by the light control film 200. The viewing angle may be limited to a predetermined angle range by the light control film 200. As an example, in an embodiment, when an imaginary line facing the driver PS1 or passenger PS2 in the front direction and extending in a direction perpendicular to the display surface of the display device 10 is taken as a normal line, the viewing angle may be an angle within about 35° from the normal line. In some embodiments, the angle within about 35° from the normal line may be defined as an effective viewing angle. However, embodiments of the present disclosure are not necessarily limited thereto.

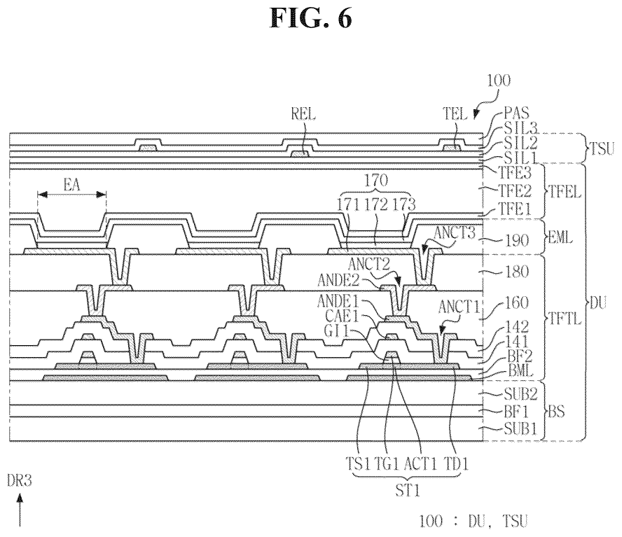

FIG. 6 is a cross-sectional view illustrating an example of a display panel according to an embodiment.

Referring to FIG. 6, the display panel 100 may include a display layer DU and a touch sensor layer TSU. In an embodiment, the display layer DU may include a base member BS, a thin film transistor layer TFTL, a light emitting element layer EML, and a thin film encapsulation layer TFEL (e.g., consecutively arranged in the third direction DR3).

In an embodiment, the base member BS may include a first substrate SUB1, a first buffer film BF1 disposed on the first substrate SUB1 (e.g., disposed directly thereon in the third direction DR3), and a second substrate SUB2 disposed on the first buffer film BF1 (e.g., disposed directly thereon in the third direction DR3).

In an embodiment, the first substrate SUB1 and the second substrate SUB2 may be made of an insulating material such as glass, quartz, or polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. However, embodiments of the present disclosure are not necessarily limited thereto. Alternatively, the substrate may also include a metal material.

The first substrate SUB1 and the second substrate SUB2 may be rigid substrates or flexible substrates that may be bent, folded, and rolled. In an embodiment in which the substrate is the flexible substrate, the substrate may be formed of polyimide PI. However, embodiments of the present disclosure are not necessarily limited thereto.

The first buffer film BF1 is a film for protecting a first thin film transistor ST1 and a light emitting layer 172 from moisture permeating through the first and second substrates SUB1 and SUB2, which are vulnerable to moisture permeation. In an embodiment, the first buffer film BF1 may be formed of a plurality of inorganic films alternately stacked (e.g., in the third direction DR3). For example, in an embodiment the first buffer film BF1 may be formed of a multi-film in which one or more inorganic films of a silicon nitride layer, a silicon oxynitride layer, a silicon oxide layer, a titanium oxide layer, and an aluminum oxide layer are alternately stacked (e.g., in the third direction DR3).

In an embodiment, the thin film transistor layer TFTL may include a lower metal layer BML, a second buffer film BF2, a first thin film transistor ST1, a first gate insulating film GI1, a first interlayer insulating film 141, a first capacitor electrode CAE1, a second interlayer insulating film 142, a first anode connection electrode ANDE1, a first organic film 160, a second anode connection electrode ANDE2, and a second organic film 180.

The lower metal layer BML may be disposed on the second substrate SUB2 (e.g., disposed directly thereon in the third direction DR3). The lower metal layer BML may be disposed to overlap a first active layer ACT1 of the first thin film transistor ST1 in the third direction DR3 to prevent leakage current from occurring when light is incident on the first active layer ACT1 of the first thin film transistor ST1. In an embodiment, the lower metal layer BML may be formed as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not necessarily limited thereto. For example, the lower metal layer BML may be omitted in some embodiments.

The second buffer film BF2 may be disposed on the lower metal layer BML (e.g., disposed directly thereon). The second buffer film BF2 is a film for protecting the first thin film transistor ST1 and the light emitting layer 172 from moisture permeating through the first and second substrates SUB1 and SUB2, which are vulnerable to moisture permeation. The second buffer film BF2 may be formed of a plurality of inorganic films alternately stacked. For example, in an embodiment the second buffer film BF2 may be formed as a multi-film in which one or more inorganic films of a silicon nitride layer, a silicon oxynitride layer, a silicon oxide layer, a titanium oxide layer, and an aluminum oxide layer are alternately stacked. However, embodiments of the present disclosure are not necessarily limited thereto.

The first active layer ACT1 of the first thin film transistor ST1 may be disposed on the second buffer film BF2 (e.g., disposed directly thereon in the third direction DR3). In an embodiment, the first active layer ACT1 of the first thin film transistor ST1 includes polycrystalline silicon, single crystal silicon, low-temperature polycrystalline silicon, amorphous silicon, or an oxide semiconductor. The first active layer ACT1 of the first thin film transistor ST1 exposed and not covered by the first gate insulating film GI1 may be doped with impurities or ions to have conductivity. Therefore, a first source electrode TS1 and a first drain electrode TD1 of the first active layer ACT1 of the first thin film transistor ST1 may be formed.

The first gate insulating film GI1 may be disposed on the first active layer ACT1 of the first thin film transistor ST1 (e.g., disposed directly thereon in the third direction DR3). It is illustrated in FIG. 6 that the first gate insulating film GI1 is disposed between a first gate electrode TG1 and the first active layer ACT1 of the first thin film transistor ST1 (e.g., in the third direction DR3). However, embodiments of the present disclosure are not necessarily limited thereto. For example, in an embodiment the first gate insulating film GI1 may also be disposed between the first interlayer insulating film 141 and the first active layer ACT1 and between the first interlayer insulating film 141 and the second buffer film BF2. In an embodiment, the first gate insulating film GI1 may be formed as an inorganic film, for example, a silicon nitride layer, a silicon oxynitride layer, a silicon oxide layer, a titanium oxide layer, or an aluminum oxide layer.

The first gate electrode TG1 of the first thin film transistor ST1 may be disposed on the first gate insulating film GI1 (e.g., disposed directly thereon in the third direction DR3). The first gate electrode TG1 of the first thin film transistor ST1 may overlap the first active layer ACT1 in the third direction DR3. In an embodiment, the first gate electrode TG1 of the first thin film transistor ST1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not necessarily limited thereto.

The first interlayer insulating film 141 may be disposed on the first gate electrode TG1 of the first thin film transistor ST1 (e.g., disposed directly thereon). In an embodiment, the first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

The first capacitor electrode CAE1 may be disposed on the first interlayer insulating film 141 (e.g., disposed directly thereon in the third direction DR3). The first capacitor electrode CAE1 may overlap the first gate electrode TG1 of the first thin film transistor ST1 in the third direction DR3. Since the first interlayer insulating film 141 has a predetermined dielectric constant, a capacitor may be formed by the first capacitor electrode CAE1, the first gate electrode TG1, and the first interlayer insulating film 141 disposed between the first capacitor electrode CAE1 and the first gate electrode TG1. In an embodiment, the first capacitor electrode CAE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not necessarily limited thereto.

The second interlayer insulating film 142 may be disposed on the first capacitor electrode CAE1 (e.g., disposed directly thereon). In an embodiment, the second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first anode connection electrode ANDE1 may be disposed on the second interlayer insulating film 142 (e.g., disposed directly thereon in the third direction DR3). In an embodiment, the first anode connection electrode ANDE1 may be connected to (e.g., directly connected thereto) the first drain electrode TD1 of the first thin film transistor ST1 through a first anode contact hole ANCT1 penetrating through the first interlayer insulating film 141 and the second interlayer insulating film 142 to expose the first drain electrode TD1 of the first thin film transistor ST1. In an embodiment, the first anode connection electrode ANDE1 may be formed of a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first organic film 160 for planarization may be disposed on the first pixel connection electrode ANDE1 (e.g., disposed directly thereon). In an embodiment, the first organic film 160 may be formed of an organic film made of an acryl resin, an epoxy resin, a phenolic resin, a polyamide resin, a polyimide resin, or the like.

The second anode connection electrode ANDE2 may be disposed on the first organic film 160 (e.g., disposed directly thereon in the third direction DR3). In an embodiment, the second anode connection electrode ANDE2 may be connected to (e.g., directly connected thereto) the first anode connection electrode ANDE1 through a second anode contact hole ANCT2 penetrating through the first organic film 160 to expose the first anode connection electrode ANDE1. In an embodiment, the second anode connection electrode ANDE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second organic film 180 may be disposed on the second anode connection electrode ANDE2 (e.g., disposed directly thereon). In an embodiment, the second organic film 180 may be formed as an organic film made of an acryl resin, an epoxy resin, a phenolic resin, a polyamide resin, a polyimide resin, or the like.

It is illustrated in FIG. 6 that the first thin film transistor ST1 is formed in a top gate type in which the first gate electrode TG1 is positioned above the first active layer ACT1. However, embodiments of the present disclosure are not necessarily limited thereto. For example, in an embodiment the first thin film transistor ST1 may be formed in a bottom gate type in which the first gate electrode TG1 is positioned below the first active layer ACT1 or a double gate type in which the first gate electrode TG1 is positioned both above and below the first active layer ACT1.

The light emitting element layer EML may be disposed on the second organic film 180 (e.g., disposed directly thereon in the third direction DR3). The light emitting element layer EML may include light emitting elements 170 and a bank 190. In an embodiment, each of the light emitting elements 170 may include a first light emitting electrode 171, a light emitting layer 172, and a second light emitting electrode 173.

The first light emitting electrode 171 may be formed on the second organic film 180 (e.g., disposed directly thereon in the third direction DR3). In an embodiment, the first light emitting electrode 171 may be connected to the second anode connection electrode ANDE2 through a third anode contact hole ANCT3 penetrating through the second organic film 180 to expose the second anode connection electrode ANDE2.

In an embodiment, the first light emitting electrode 171 may be formed on the second organic film 180 (e.g., disposed directly thereon in the third direction DR3). In an embodiment, the first light emitting electrode 171 may be connected to the second anode connection electrode ANDE2 through a third anode contact hole ANCT3 penetrating through the second organic film 180 to expose the second anode connection electrode ANDE2.

In an embodiment including a top emission structure in which light is emitted toward the second light emitting electrode 173 based on the light emitting layer 172, the first light emitting electrode 171 may be formed of a metal material having high reflectance, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the first light emitting electrode 171 on the second organic film 180 to define a light emitting area EA. The bank 190 may include an opening that exposes at least a portion of an upper surface of the first light emitting electrode 171. For example, in an embodiment the bank 190 may expose a central portion of the first light emitting electrode 171 and the bank 190 may be formed to cover an edge of the first light emitting electrode 171. In an embodiment, the bank 190 may be formed of an organic film such as an acrylic resin, an epoxy resin, a phenolic resin, a polyamide resin, or a polyimide resin.

The light emitting area EA refers to an area in which the first light emitting electrode 171, the light emitting layer 172, and the second light emitting electrode 173 are sequentially stacked and holes from the first light emitting electrode 171 and electrons from the second light emitting electrode 173 are bonded to each other in the light emitting layer 172 to emit light. The light emitting area EA may be defined by, and may correspond with, the opening of the bank 190.

The light emitting layer 172 is formed on the first light emitting electrode 171 and the bank 190. In an embodiment, the light emitting layer 172 may be disposed within the opening of the bank 190. However, embodiments of the present disclosure are not necessarily limited thereto. The light emitting layer 172 may include an organic material to emit light of a predetermined color. For example, in an embodiment the light emitting layer 172 may include a hole transporting layer, an organic material layer, and an electron transporting layer.

The second light emitting electrode 173 may be disposed on the light emitting layer 172 (e.g., in the third direction DR3). The second light emitting electrode 173 may be formed to cover the light emitting layer 172. In an embodiment, the second light emitting electrode 173 may be a common layer commonly formed in all the light emitting areas EA. In an embodiment, a capping layer may be formed on the second light emitting electrode 173.

In an embodiment having the top emission structure, the second light emitting electrode 173 may be formed of transparent conductive oxide (TCO) such as indium tin oxide (ITO) or indium zinc oxide (IZO) capable of transmitting light, or a semi-transmissive conductive material such as magnesium (Mg), silver (Ag), or an alloy of magnesium (Mg) and silver (Ag). When the second light emitting electrode 173 is formed of the semi-transmissive conductive material, light emission efficiency may be increased by a micro cavity.

The thin film encapsulation layer TFEL may be disposed on the second light emitting electrode 173 (e.g., disposed directly thereon in the third direction DR3). In an embodiment, the thin film encapsulation layer TFEL may include at least one inorganic film to prevent oxygen or moisture from permeating into the light emitting element layer. In addition, the thin film encapsulation layer TFEL may include at least one organic film to protect the light emitting element layer from foreign substances such as dust. For example, in an embodiment the thin film encapsulation layer TFEL may include a first encapsulation film TFE1, a second encapsulation film TFE2, and a third encapsulation film TFE3 (e.g., consecutively stacked in the third direction DR3).

The first encapsulation film TFE1 (e.g., a first inorganic encapsulation film) may be disposed on the second light emitting electrode 173 (e.g., disposed directly thereon in the third direction DR3). The first encapsulation film TFE1 may be an inorganic film of a single layer or a multi-layer. In an embodiment, the first encapsulation film TFE1 may be formed of a single film or a multi-film in which one or more inorganic films of a silicon nitride layer, a silicon oxynitride layer, a silicon oxide layer, a titanium oxide layer, and an aluminum oxide layer are alternately stacked (e.g., in the third direction DR3).

The second encapsulation film TFE2 (e.g., a first organic encapsulation film) may be disposed on the first encapsulation film TFE1 (e.g., disposed directly thereon in the third direction DR3). The second encapsulation film TFE2 may be an organic film of a single layer or a multi-layer. In an embodiment, the second encapsulation film TFE2 may include a polymer-based material. Examples of the polymer-based material may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate, polyacrylic acid, etc.), or any combination thereof.

The third encapsulation film TFE3 (e.g., a second inorganic encapsulation film) may be disposed on the second encapsulation film TFE2 (e.g., disposed directly thereon in the third direction DR3). The third encapsulation film TFE3 may be an inorganic film of a single layer or a multi-layer. In an embodiment, the third encapsulation film TFE3 may include the same material as the first encapsulation film TFE1. For example, the third encapsulation film TFE3 may be formed of a single film or a multi-film in which one or more inorganic films of a silicon nitride layer, a silicon oxynitride layer, a silicon oxide layer, a titanium oxide layer, and an aluminum oxide layer are alternately stacked (e.g., in the third direction DR3).

The touch sensor layer TSU may be disposed on the thin film encapsulation layer TFEL (e.g., disposed directly thereon in the third direction DR3). The touch sensor layer TSU may include a plurality of touch electrodes for sensing a user's touch in a capacitance method, and touch lines connecting the plurality of touch electrodes and the touch driver. For example, the touch sensor layer TSU may sense the user's touch in a mutual capacitance method or a self-capacitance method.

In an embodiment, the touch sensor layer TSU may be disposed on a separate substrate disposed on the display layer DU. In this embodiment, the substrate supporting the touch sensor layer TSU may be an encapsulation member that encapsulates the display layer DU.

The plurality of touch electrodes of the touch sensor layer TSU may be disposed in a touch sensor area overlapping the display area. The touch lines of the touch sensor layer TSU may be disposed in a touch peripheral area overlapping the non-display area.

In an embodiment, the touch sensor layer TSU may include a first touch insulating film SIL1, a first touch electrode REL, a second touch insulating film SIL2, a second touch electrode TEL, and a third touch insulating film SIL3.

The first touch insulating film SIL1 may be disposed on the thin film encapsulation layer TFEL (e.g., disposed directly thereon in the third direction DR3). The first touch insulating film SIL1 may have insulation and optical functions. The first touch insulating film SIL1 may include at least one inorganic film. For example, in an embodiment the first touch insulating film SIL1 may be an inorganic film including at least one of a silicon nitride layer, a silicon oxynitride layer, a silicon oxide layer, a titanium oxide layer, and an aluminum oxide layer. However, embodiments of the present disclosure are not necessarily limited thereto. For example, in some embodiments the first touch insulating film SIL1 may be omitted.

The first touch electrode REL may be disposed on the first touch insulating film SIL1 (e.g., disposed directly thereon in the third direction DR3). The first touch electrode REL may not overlap the light emitting element 170 (e.g., in the third direction DR3). In an embodiment, the first touch electrode REL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The second touch insulating film SIL2 may cover the first touch electrode REL and the first touch insulating film SIL1. The second touch insulating film SIL2 may have insulation and optical functions. For example, in an embodiment the second touch insulating film SIL2 may be made of the materials illustrated in the first touch insulating film SIL1.

The second touch electrode TEL may be disposed on the second touch insulating film SIL2 (e.g., disposed directly thereon in the third direction DR3). The second touch electrode TEL may not overlap the light emitting element 170 (e.g., in the third direction DR3). In an embodiment, the second touch electrode TEL may be formed as a single layer made of molybdenum (Mo), titanium (Ti), copper (Cu), aluminum (Al), or indium tin oxide (ITO), or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The third touch insulating film SIL3 may cover the second touch electrode TEL and the second touch insulating film SIL2. The third touch insulating film SIL3 may have insulation and optical functions. In an embodiment, the third touch insulating film SIL3 may be made of the materials illustrated in the second touch insulating film SIL2.

In some embodiments, the first touch insulating film SIL1, the second touch insulating film SIL2, and the third touch insulating film SIL3 may be organic films. For example, in an embodiment the first touch insulating film SIL1, the second touch insulating film SIL2, and the third touch insulating film SIL3 may be organic films made of an acryl resin, an epoxy resin, a phenolic resin, a polyamide resin, a polyimide resin, or the like.

The touch sensor layer TSU may further include a planarization film PAS for planarization. The planarization film PAS may be disposed on the third touch insulating film SIL3 (e.g., disposed directly thereon in the third direction DR3). In an embodiment, the planarization film PAS may be formed of an organic film made of an acrylic resin, an epoxy resin, a phenolic resin, a polyamide resin, a polyimide resin, or the like.

FIG. 7A is a cross-sectional view illustrating a polarizing film according to an embodiment. FIG. 7B is a cross-sectional view illustrating a polarizing film according to an embodiment.

Referring to FIGS. 7A and 7B, a polarizing film 300 according to an embodiment may include a polarizing layer 310, a phase retardation layer 320, a phase compensation layer 330, a first protective layer 340, and a second protective layer 350.

The polarizing layer 310 may polarize light incident on the polarizing layer 310 into light in the same direction as a polarization axis. In an embodiment, the polarizing layer 310 may be composed of a polyvinyl alcohol (PVA) film containing a polarizer and/or a dichroic dye. In an embodiment, the dichroic dye may be an iodine molecule or/and a dye molecule.

In an embodiment, the polarizing layer 310 may be formed by stretching a polyvinyl alcohol film in one direction and immersing a polyvinyl alcohol film in a solution of iodine or/and dichroic dye. In this embodiment, the iodine molecules or/and the dichroic dye molecules may be arranged side by side in the stretching direction. Since the iodine molecules and the dye molecules exhibit dichroism, the iodine molecules and the dye molecules may absorb light vibrating in the stretching direction and transmit light vibrating in a direction perpendicular to the stretching direction.

The phase retardation layer 320 may be disposed below the polarizing layer 310 (e.g., in a direction opposite to the third direction DR3). The phase retardation layer 320 may serve to retard a phase of polarized light passing through the polarizing layer 310. Light passing through the phase retardation layer 320 may be circularly or elliptically polarized. Accordingly, external light reflectance may be reduced. The phase retardation layer 320 may be disposed farther from the light source than the polarizing layer 310. For example, when external light is incident from the top of the polarizing layer 310, the phase retardation layer 320 may be disposed below the polarizing layer 310 (e.g., in a direction opposite to the third direction DR3).

In an embodiment, the phase retardation layer 320 may be a positive A plate. However, embodiments of the present disclosure are not necessarily limited thereto and the phase retardation layer 320 may be one of a negative A plate, a positive C plate, or a negative C plate in some embodiments. The phase retardation layer 320 may be a quarter wave plate (QWP). In an embodiment, the phase retardation layer 320 may include at least one of polycarbonate (PC), tri-acetyl cellulous (TAC), and cyclo olefin polymer.

The phase compensation layer 330 may be disposed below the phase retardation layer 320 (e.g., in a direction opposite to the third direction DR3). In an embodiment, the phase compensation layer 330 may be a positive C plate. However, embodiments of the present disclosure are not necessarily limited thereto and the phase compensation layer 330 may be one of a positive A plate, a negative A plate, or a negative C plate in some embodiments. In an embodiment, the phase compensation layer 330 may include at least one of polycarbonate (PC), tri-acetyl cellulous (TAC), and cyclo olefin polymer. However, embodiments of the present disclosure are not necessarily limited thereto and in some embodiments, the phase compensation layer 330 may be omitted.

The first protective layer 340 and the second protective layer 350 may be disposed on (e.g., disposed directly thereon) upper and lower surfaces of the polarizing layer 310. The first protective layer 340 and the second protective layer 350 may serve to support the polarizing layer 310 and supplement a mechanical strength of the polarizing layer 310. In an embodiment, the first protective layer 340 and the second protective layer 350 may include tri-acetyl cellulous (TAC), cyclo olefin polymer, polymethyl methacrylate (PMMA), and polyethylene terephthalate (PET), etc.

A first adhesive layer 360 may be disposed between the second protective layer 350 and the phase retardation layer 320 (e.g., in the third direction DR3). The first adhesive layer 360 may serve to attach the phase retardation layer 320 to a lower portion of the second protective layer 350. In an embodiment, the first adhesive layer 360 may be a pressure sensitive adhesive (PSA). For example, the first adhesive layer 360 may be an acrylic pressure sensitive adhesive.

A second adhesive layer 370 may be disposed between the phase retardation layer 320 and the phase compensation layer 330 (e.g., in the third direction DR3). The second adhesive layer 370 may serve to attach the phase compensation layer 330 to a lower portion of the phase retardation layer 320. In an embodiment, the second adhesive layer 370 may be a pressure sensitive adhesive (PSA). For example, the second adhesive layer 370 may be an acrylic pressure sensitive adhesive. In some embodiments, when the phase compensation layer 330 is omitted, the second adhesive layer 370 may also be omitted.

In some embodiments, as illustrated in FIG. 7A, the phase retardation layer 320 may be disposed on the phase compensation layer 330 (e.g., in the third direction DR3), and the polarizing layer 310 may be disposed on the phase retardation layer 320 (e.g., in the third direction DR3). However, as described above, the second adhesive layer 370 may be disposed between the phase compensation layer 330 and the phase retardation layer 320 (e.g., in the third direction DR3), and the first adhesive layer 360 and the second protective layer 350 may be disposed between the phase retardation layer 320 and the polarizing layer 310 (e.g., in the third direction DR3).

In an embodiment, as illustrated in FIG. 7B, the phase compensation layer 330 may be disposed on the phase retardation layer 320 (e.g., in the third direction DR3), and the polarizing layer 310 may be disposed on the phase compensation layer 330 (e.g., in the third direction DR3). In this embodiment, the second adhesive layer 370 may be provided between the phase retardation layer 320 and the phase compensation layer 330 (e.g., in the third direction DR3), and the first adhesive layer 360 and the second protective layer 350 may be provided between the phase compensation layer 330 and the polarizing layer 310 (e.g., in the third direction DR3).

A third adhesive layer 380 may be disposed on the first protective layer 340 (e.g., disposed directly thereon in the third direction DR3). The third adhesive layer 380 may serve to attach the polarizing film 300 and the cover window described above in FIG. 4. In an embodiment, the third adhesive layer 380 may include a photocurable resin, for example, a UV-curable resin. The third adhesive layer 380 may include an acrylic resin, such as an acrylic ester-based material.

A fourth adhesive layer 390 may be disposed below the phase retardation layer 320 (e.g., directly below in a direction opposite to the third direction DR3). The fourth adhesive layer 390 may serve to attach the polarizing film 300 and the light control film 200 (see FIG. 4) described above in FIG. 4. In an embodiment, the fourth adhesive layer 390 may be a pressure sensitive adhesive (PSA). For example, the fourth adhesive layer 390 may be an acrylic pressure sensitive adhesive.

In some embodiments, the polarizing film 300 may include a phase adjustment layer and a polarization protective layer. The polarization protective layer may be disposed on the phase adjustment layer. For example, the display device 10 may be stacked (e.g., in the third direction DR3) in the following order: the display panel 100 (see FIG. 4), the light control film 200 (see FIG. 4), the phase adjustment layer, and the polarization protective layer.

In an embodiment, the phase adjustment layer may include at least one of the polarizing layer 310, the phase retardation layer 320, and the phase compensation layer 330. As an example, the phase adjustment layer may include only the polarizing layer 310, and as another example, the phase adjustment layer may include only the polarizing layer 310 and the phase retardation layer 320. However, embodiments of the present disclosure are not necessarily limited to the above-described examples.

In an embodiment, the polarization protective layer may include at least one of the first protective layer 340 and the second protective layer 350. For example, the polarization protective layer may include only the first protective layer 340 on the polarizing layer 310. However, embodiments of the present disclosure are not necessarily limited thereto.

FIG. 8 is a cross-sectional view illustrating a light control film according to an embodiment.

Referring to FIG. 8, the light control film 200 may be disposed on the display panel 100. In an embodiment, the light control film 200 may include a light control layer 210, a base film layer 220, and a fifth adhesive layer 230.

The light control layer 210 may control a viewing angle of light emitted from the light emitting layer 172. For example, when first light LG1 emitted from the light emitting layer 172 travels at an angle that is less than or equal to a predetermined angle with respect to the third direction DR3, the first light LG1 may be emitted to the outside (e.g., the external environment) through a light transmission pattern 211. However, when second light LG2 emitted from the light emitting layer 172 travels at an angle that is greater than or equal to a predetermined angle with respect to the third direction DR3, the second light LG2 may be absorbed or blocked by the light blocking film LS and not emitted to the outside (e.g., the external environment).

The light control layer 210 may include a light transmission pattern 211 and a light blocking pattern 212.

The light transmission pattern 211 may be disposed on the base film layer 220. The light transmission pattern 211 may be disposed below the base film layer 220 (e.g., in the direction opposite to the third direction DR3). In an embodiment, the light transmission pattern 211 may be disposed across the transmissive area OA and the non-transmissive area LSA. The light transmission pattern 211 may transmit the light emitted from the light emitting layer 172.

The light transmission pattern 211 may include a transparent organic material. For example, in an embodiment the light transmission pattern 211 may include an organic film made of an acryl resin, an epoxy resin, a phenolic resin, a polyamide resin, a polyimide resin, or the like. In an embodiment, the light transmission pattern 211 may include silicon oxynitride or silicon oxide.

In some embodiments, the light transmission pattern 211 may include a first portion 211a that overlaps the light blocking pattern 212 in a horizontal direction perpendicular to the third direction DR3, and a second portion 211b disposed on the first portion 211a (e.g., disposed directly thereon in the third direction DR3). The first portion 211a may be disposed in the transmissive area OA. The first portion 211a may be disposed alternately with the light blocking pattern 212 in the horizontal direction perpendicular to the third direction DR3. The second portion 211b may be disposed across the transmissive area OA and the non-transmissive area LSA. The second portion 211b may overlap the first portion 211a and the light blocking pattern 212 in the third direction DR3. The light transmission pattern 211 may include a groove disposed in the non-transmissive area LSA.

However, embodiments of the present disclosure are not necessarily limited thereto. For example, in an embodiment the second portion 211b may be omitted. In this embodiment, the light blocking pattern 212 may be disposed directly on the base film layer 220 (e.g., in a direction opposite to the third direction DR3).

In an embodiment, the light blocking pattern 212 may be disposed alternately with the first portion 211a of the light transmission pattern 211 (e.g., in the horizontal direction perpendicular to the third direction DR3). The light blocking pattern 212 may be disposed on the second portion 211b of the light transmission pattern 211 (e.g., directly thereon in a direction opposite to the third direction DR3). The light blocking pattern 212 may be disposed below the second portion 211b of the light transmission pattern 211. The light blocking pattern 212 may be disposed within the groove of the light transmission pattern 211. The light blocking pattern 212 may absorb or block the light emitted from the light emitting layer 172.

The light blocking pattern 212 may include a light blocking organic material. For example, in an embodiment the light blocking pattern 212 may include an organic material including an organic black pigment such as carbon black, as a photosensitive resin capable of absorbing or blocking light.

In some embodiments, the light blocking pattern 212 may have a shape having a width (e.g., length in the horizontal direction perpendicular to the third direction DR3) that becomes narrower from the bottom to the top. For example, the light blocking pattern 212 may have a shape having a width that becomes narrower in the third direction DR3. For example, the width of the light blocking pattern 212 may become narrower as it approaches the base film layer 220. However, embodiments of the present disclosure are not necessarily limited thereto. For example, in an embodiment the width of the light blocking pattern 212 may be constant along the third direction DR3.

The base film layer 220 may support the light control layer 210. For example, the base film layer 220 may provide a space in which the light control layer 210 may be formed when manufacturing the light control film 200.

In some embodiments, the base film layer 220 may include at least one of polyethylene terephthalate (PET), polycarbonate (PC), and tri-acetyl cellulous (TAC).

The light control film 200 may be manufactured by forming the light control layer 210 on the base film layer 220 (e.g., in the third direction DR3). For example, in an embodiment the light transmission pattern 211 may be formed by applying a light transmitting material layer containing transparent liquid resin on the base film layer 220, forming a groove using a roller or jig, and then curing the light transmitting material layer while maintaining a shape of the groove. The light blocking pattern 212 may be formed by applying a light blocking material layer containing black pigment and liquid resin to the groove and then curing the light blocking material layer. In some embodiments, the curing of the light transmitting material layer and the light blocking material layer may be ultraviolet curing.

The fifth adhesive layer 230 may be disposed on the light control layer 210 (e.g., disposed directly thereon in the direction opposite to the third direction DR3). The fifth adhesive layer 230 may be disposed below the light control layer 210. The fifth adhesive layer 230 may serve to attach the light control film 200 and the display panel 100 to each other. In an embodiment, the fifth adhesive layer 230 may be a pressure sensitive adhesive (PSA). For example, the fifth adhesive layer 230 may be an acrylic pressure sensitive adhesive.

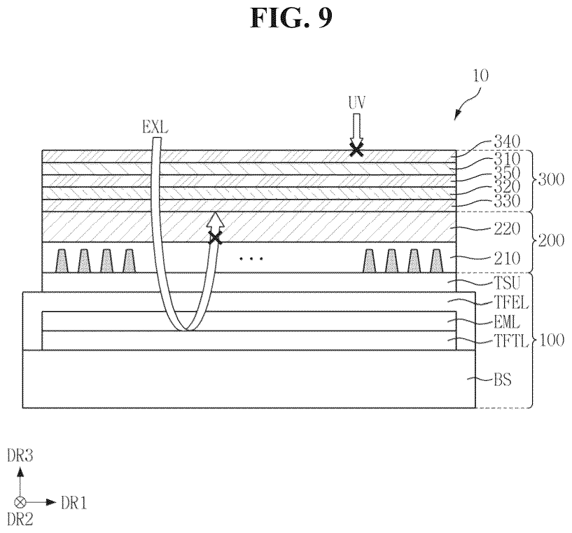

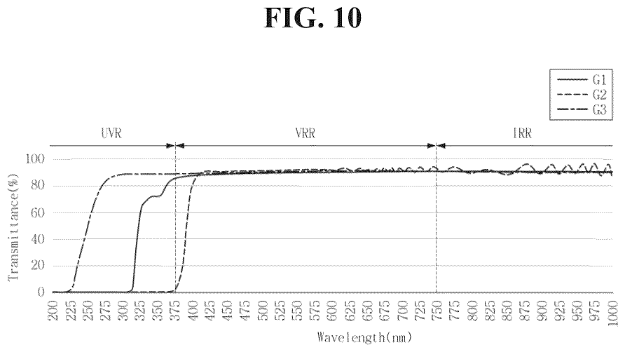

FIG. 9 is a cross-sectional view illustrating a display device according to an embodiment. FIG. 10 is a graph illustrating light transmittance for each wavelength of a base film layer of a light control film according to a first comparative example, a protective layer of a polarizing film according to an embodiment of the present disclosure, and a base film layer of a light control film according to an embodiment of the present disclosure. In FIG. 9, the first to fifth adhesive layers 360, 370, 380, 390, and 230 are omitted.

Referring to FIGS. 9 and 10, the light control film 200 may be disposed on the display panel 100 (e.g., disposed directly thereon in the third direction DR3). The polarizing film 300 may be disposed on the light control film 200 (e.g., disposed directly thereon in the third direction DR3). The light control film 200 may be disposed between the display panel 100 and the polarizing film 300 (e.g., in the third direction DR3). The display device 10 may be stacked (e.g., in the third direction DR3) in the following order: the display panel 100, the light control film 200, and the polarizing film 300.

Ultraviolet (UV) transmittance of the first protective layer 340 and the second

protective layer 350 of the polarizing film 300 may be lower than ultraviolet (UV) transmittance of the base film layer 220 of the light control film 200. For example, the first protective layer 340 and the second protective layer 350 of the polarizing film 300 may block most of the emitted ultraviolet (UV).

For example, in an embodiment the average ultraviolet (UV) transmittance of the first protective layer 340 and the second protective layer 350 of the polarizing film 300 may be less than or equal to about 5%. In the present specification, ultraviolet (UV) may refer to light with a wavelength less than or equal to about 375 nm. For example, as illustrated in FIG. 10, ultraviolet (UV) may be light included in an ultraviolet range (UVR) with a wavelength less than or equal to about 375 nm, visible light may be light included in a visible light region (VRR) with a wavelength in a range of about 375 nm to about 750 nm, and infrared may be light included in an infrared region (IRR) with a wavelength greater than about 750 nm. The average ultraviolet (UV) transmittance may refer to average transmittance for ultraviolet in the range less than or equal to about 375 nm.

A first graph G1 illustrated in FIG. 10 is a graph illustrating light transmittance of the base film layer 220 of the light control film 200 according to a first comparative example, a second graph G2 is a graph illustrating light transmittance of the first protective layer 340 and the second protective layer 350 of the polarizing film 300 according to an embodiment of the present disclosure, and a third graph G3 is a graph illustrating light transmittance of the base film layer 220 of the light control film 200 according to an embodiment of the present disclosure. The base film layer 220 of the light control film 200 according to the first comparative

example may include polyethylene terephthalate (PET). The first protective layer 340 and the second protective layer 350 of the polarizing film 300 according to an embodiment of the present disclosure may include tri-acetyl cellulous (TAC), and the base film layer 220 of the light control film 200 according to an embodiment of the present disclosure may include tri-acetyl cellulous (TAC).

As illustrated in FIG. 10, the base film layer 220 of the light control film 200 according to the first comparative example including polyethylene terephthalate (PET) and the base film layer 220 of the light control film 200 according to an embodiment including tri-acetyl cellulous may have a transmittance of 80% or more to ultraviolet (UV) with a wavelength of 375 nm. In contrast, the first protective layer 340 and the second protective layer 350 of the polarizing film 300 according to an embodiment of the present disclosure including tri-acetyl cellulous may have a transmittance of 3% or less to ultraviolet (UV) with a wavelength of 375 nm.

In some embodiments, the first protective layer 340 and the second protective layer 350 of the polarizing film 300 according to an embodiment may further include an ultraviolet absorber. In an embodiment, the first protective layer 340 and the second protective layer 350 of the polarizing film 300 according to an embodiment may perform an ultraviolet (UV) blocking function. Accordingly, the first protective layer 340 and the second protective layer 350 of the polarizing film 300 according to an embodiment may prevent the polarizing layer 310 from being damaged by ultraviolet (UV).

The display device 10 according to the present embodiment may prevent yellowing of the light control film 200 caused by ultraviolet (UV) by disposing the polarizing film 300 on the light control film 200 (e.g., above the light control film 200 in the third direction DR3).

For example, the base film layer 220 of the light control film 200 according to an embodiment needs to transmit at least a portion of ultraviolet (UV) to cure the light transmission pattern 211 when manufacturing the light control film 200. Since a roller or jig through which ultraviolet is difficult to pass through is disposed on a surface where the groove of the light transmission pattern 211 is formed, the base film layer 220 needs to transmit at least a portion of ultraviolet (UV) to cure the light transmission pattern 211.

The display device 10 according to an embodiment of the present embodiment may prevent the light control film 200 from yellowing due to ultraviolet (UV) even when exposed to sunlight for a long time, by disposing the polarizing film 300 on the base film layer 220 of the light control film 200 (e.g., in the third direction DR3), which may transmit at least a portion of ultraviolet (UV).

In an embodiment, a birefringence of the light control film 200 may be less than or equal to about 0.03. For example, in an embodiment the birefringence of the light control film 200 may be 0. The birefringence (An) may be defined as a difference (Δn=nₑ−n₀) between a refractive index (nₑ) in a direction with a different speed depending on a traveling direction and a refractive index (n₀) in a direction with a constant speed regardless of a traveling direction of light. In some embodiments, the light control film 200 may include tri-acetyl cellulous (TAC) having a low birefringence. An SCI reflectance of the display device 10 according to an embodiment may be less than or equal to about 5.5%.

The display device 10 according to an embodiment may prevent a phase of external light EXL, having a phase that is adjusted to be constant by being incident on the polarizing film 300, from being distorted again when passing through the light control film 200, by minimizing the birefringence of the light control film 200 between the polarizing film 300 and the display panel 100. Accordingly, the external light EXL reflected from the display panel 100 ultimately does not pass through the polarizing film 300, and an external light EXL reflection of the display device 10 may be reduced.

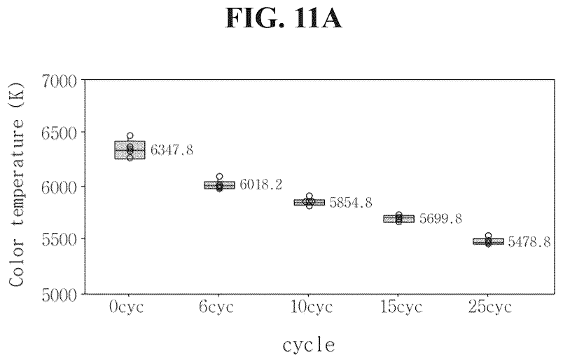

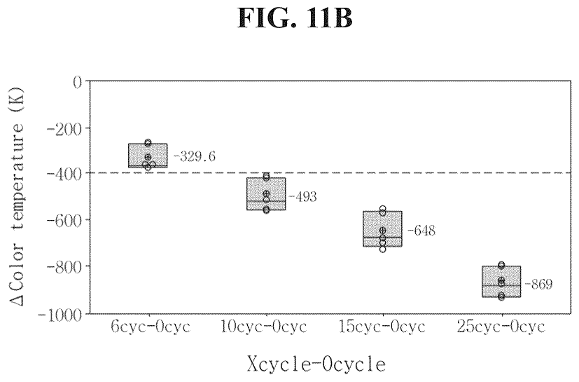

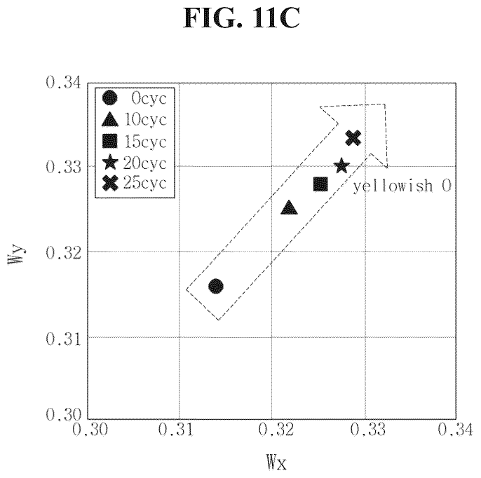

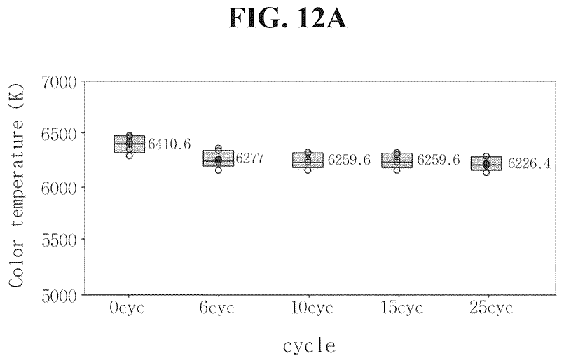

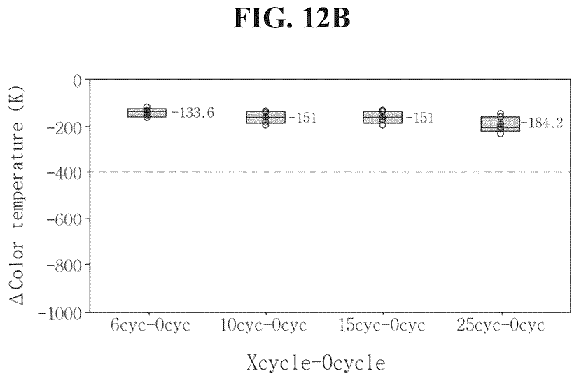

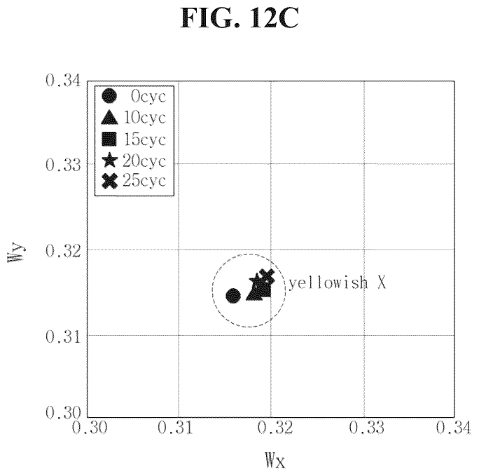

FIGS. 11A to 11C are graphs illustrating solar test results of a display device according to a second comparative example. FIGS. 12A to 12C are graphs illustrating solar test results of a display device according to an embodiment.

Referring to FIGS. 11A to 12C in addition to FIGS. 9 and 10, the display device 10 according to the second comparative example of FIGS. 11A to 11C may be stacked (e.g., in the third direction DR3) in the following order: the display panel 100, the polarizing film 300, and the light control film 200. The display device 10 according to an embodiment of FIGS. 12A to 12C may be stacked (e.g., in the third direction DR3) in the following order: the display panel 100, the light control film 200, and the polarizing film 300.

FIGS. 11A and 11B are graphs measuring a color temperature of the display device 10 after performing a solar test on the display device 10 according to the second comparative example, and FIGS. 12A and 12B are graphs measuring a color temperature of the display device 10 after performing a solar test on the display device 10 according to an embodiment. FIG. 11C is a graph measuring color coordinates of the display device 10 after performing a solar test on the display device 10 according to the second comparative example, and FIG. 12C is a graph measuring color coordinates of the display device 10 after performing a solar test on the display device 10 according to an embodiment. The color coordinates (Wx, Wy) illustrated in FIGS. 11C and 12C represent color coordinates of CIE 1931.

The solar test performed to derive the results of FIGS. 11A to 12C was conducted by irradiating light so that a temperature inside a chamber was 65° C. and a surface temperature of the display device 10 was 85° C. using a solar lamp with an integrated value of power (Watt: W) per unit area (m²) of 48 W/m² in a wavelength range of 300 nm to 400 nm, and an integrated value of power (Watt: W) per unit area (m²) of 830 W/m² in a wavelength range of 280 nm to 3000 nm within the chamber of 25° C. One cycle includes a light irradiation period in which light is irradiated for 8 hours and a rest period in which light is not irradiated for 8 hours. The solar test was conducted under conditions of 65° C. in the chamber and a relative humidity of 30% or less during 0 to 15 cycles, and was conducted under conditions of 65° C. in the chamber and a relative humidity of 50% or more for 16 to 25 cycles.

As described above with reference to FIGS. 9 and 10, in an embodiment the ultraviolet (UV) transmittance of the base film layer 220 of the light control film 200 may be greater than the ultraviolet (UV) transmittance of the first protective layer 340 and the second protective layer 350 of the polarizing film 300 so that the light transmission pattern 211 may be sufficiently cured when forming the light control layer 210. In this case, while the display device 10 according to the second comparative example does not have an upper layer that may block ultraviolet (UV), the display device 10 according to an embodiment of the present disclosure has the polarizing film 300 that blocks ultraviolet (UV). Therefore, the yellowing may be reduced.

As illustrated in FIGS. 11A and 11B, according to the display device 10 according to the second comparative example, in which the display panel 100, the polarizing film 300, and the light control film 200 are stacked in that order (e.g., in the third direction DR3), as the solar test is conducted from 0 cycle (initial) to 6 cycle, 10 cycle, 15 cycle, and 25 cycle, the color temperature may be significantly reduced.

For example, according to the display device 10 according to the second comparative example, a color temperature difference between 6 cycle and 0 cycle may be approximately 329.6K, a color temperature difference between 10 cycle and 0 cycle may be approximately 493K, a color temperature difference between 15 cycle and 0 cycle may be approximately 648K, and a color temperature difference between 25 cycle and 0 cycle may be approximately 869K.

In contrast, as illustrated in FIGS. 12A and 12B, according to the display device 10 according to an embodiment, in which the display panel 100, the light control film 200, and the polarizing film 300 are stacked in that order (e.g., in the third direction DR3), as the solar test is conducted from 0 cycle (initial) to 6 cycle, 10 cycle, 15 cycle, and 25 cycle, the color temperature may be slightly reduced. As an example, in the display device 10 according to an embodiment, a color temperature difference between 25 cycle and 0 cycle in the solar test may be approximately 400K or less, such as approximately 200K or less.

For example, in the display device 10 according to an embodiment, a color temperature difference between 6 cycle and 0 cycle may be approximately 133.6K, a color temperature difference between 10 cycle and 0 cycle may be approximately 151K, a color temperature difference between 15 cycle and 0 cycle may be approximately 151K, and a color temperature difference between 25 cycle and 0 cycle may be approximately 184.2K.

In contrast, as illustrated in FIG. 11C, the display device 10 according to the second comparative example, in which the display panel 100, the polarizing film 300, and the light control film 200 are stacked in that order (e.g., in the third direction DR3), as the solar test is conducted from 0 cycle (initial) to 6 cycle, 10 cycle, 15 cycle, and 25 cycle, the color coordinates (Wx, Wy) may be significantly increased. For example, the color coordinates (Wx, Wy) may move upward and to the right in a color coordinate system as the cycle of the solar test is conducted.

In contrast, as illustrated in FIG. 12C, the display device 10 according to an embodiment, in which the display panel 100, the light control film 200, and the polarizing film 300 are stacked in that order (e.g., in the third direction DR3), as the solar test is conducted from 0 cycle (initial) to 6 cycle, 10 cycle, 15 cycle, and 25 cycle, the color coordinates (Wx, Wy) may be hardly increased. For example, the color coordinates (Wx, Wy) may hardly move upward and to the right in the color coordinate system as the cycle of the solar test is conducted.

The yellowing progresses as the color temperature is reduced and the color coordinates are increased. The display device 10 according to an embodiment may minimize the yellowing by disposing the polarizing film 300 on the light control film 200.

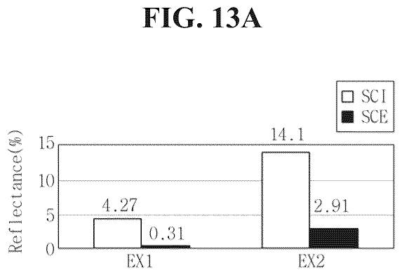

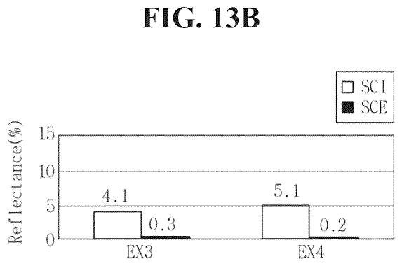

FIGS. 13A and 13B are graphs illustrating external light reflectance of a display device according to third to fifth comparative examples and an embodiment of the present disclosure.

Referring to FIGS. 13A and 13B in addition to FIG. 9, a first experimental group EX1 measured a reflectance of the display device 10 according to a third comparative example, a second experimental group EX2 measured a reflectance of the display device 10 according to a fourth comparative example, a third experimental group EX3 measured a reflectance of the display device 10 according to a fifth comparative example, and a fourth experimental group EX4 measured a reflectance of the display device 10 according to an embodiment of the present disclosure.

The display device 10 according to the third and fifth comparative examples may be stacked (e.g., in the third direction DR3) in the following order: the display panel 100, the polarizing film 300, and the light control film 200. The display device 10 according to the fourth comparative example and an embodiment of the present disclosure may be stacked (e.g., in the third direction DR3) in the following order: the display panel 100, the light control film 200, and the polarizing film 300.

In the display device 10 according to the third and fourth comparative examples, the base film layer 220 may include polyethylene terephthalate (PET). In the display device 10 according to the fifth comparative example and an embodiment, the base film layer 220 may include tri-acetyl cellulous (TAC).

As described above with reference to FIG. 9, in the display device 10 according to an embodiment, the birefringence of the light control film 200 may be less than or equal to about 0.03. In this embodiment, the light control film 200 may include tri-acetyl cellulous to achieve a low birefringence. The tri-acetyl cellulous may have a lower refractive index than polyethylene terephthalate due to its molecular structure and manufacturing process. An SCI reflectance of the display device 10 according to an embodiment of the present disclosure may be less than or equal to about 5.5%.

As illustrated in FIGS. 13A and 13B, in the first experimental group EX1 and the third experimental group EX3, since the display panel 100, the polarizing film 300, and the light control film 200 are stacked in that order (e.g., in the third direction DR3), a phase of the external light EXL may not change due to another member while the external light EXL that has passed through the polarizing film 300 is reflected by the display panel 100 and reaches the polarizing film 300 again. Accordingly, external light EXL reflectance may be minimized. For example, in the first experimental group EX1 and the third experimental group EX3, an SCI reflectance may be approximately 5% or less, and an SCE reflectance may be approximately 0.3%.

A specular component included (SCI) reflectance refers to a total ray reflectance, and a specular component excluded (SCE) reflectance may refer to a diffuse ray reflectance.

In the second experimental group EX2 and the fourth experimental group EX4, since

the display panel 100, the light control film 200, and the polarizing film 300 are stacked in that order (e.g., in the third direction DR3), the phase of external light EXL may be affected by the light control film 200 while the external light EXL that has passed through the polarizing film 300 is reflected by the display panel 100 and reaches the polarizing film 300 again.

For example, when the birefringence of the light control film 200 is greater than about 0.03, the phase of the external light EXL is shifted by the light control film 200, so that the external light EXL reflected from the display panel 100 may be emitted to the outside (e.g., the external environment) without being blocked by the polarizing film 300. In contrast, when the birefringence of the light control film 200 is less than or equal to about 0.03, such as the birefringence is 0, the phase of the external light EXL is not changed by the light control film 200. Therefore, the external light EXL reflected from the display panel 100 may be blocked by the polarizing film 300. Accordingly, external light reflection of the display device 10 may be reduced.

In the second experimental group EX2, the base film layer 220 may include polyethylene terephthalate. Due to polyethylene terephthalate having a relatively high birefringence, the second experimental group EX2 may have a high reflectance of approximately 14.1% in SCI reflectance and approximately 2.91% in SCE reflectance.

In contrast, in the fourth experimental group EX4, the base film layer 220 may include tri-acetyl cellulous. Due to tri-acetyl cellulous having a relatively low birefringence, the fourth experimental group EX4 may have a low reflectance of approximately 5.1% in SCI reflectance and approximately 0.2% in SCE reflectance.

The display device 10 according to an embodiment of the present embodiment may minimize the yellowing by including a stacked structure like the second experimental group EX2 and the fourth experimental group EX4, and may reduce the external light reflection by having the base film layer 220 including tri-acetyl cellulous with a low birefringence index like the fourth experimental group EX4.

The display device 10 according to an embodiment of the present disclosure may ensure that the light transmission pattern 211 is cured sufficiently by using the base film layer 220 with a high transmittance to ultraviolet (UV). However, the display device 10 according to an embodiment of the present disclosure may minimize the yellowing of the light control film 200 by disposing the polarizing film 300, which includes the first protective layer 340 and the second protective layer 350 with a low transmittance to ultraviolet (UV), on the base film layer 220 (e.g., in the third direction DR3) with a high transmittance to ultraviolet (UV). In addition, by minimizing the birefringence of the light control film 200 disposed between the polarizing film 300 and the display panel 100, the external light reflection of the display device 10 may be reduced.

Hereinafter, the display device according to an embodiment will be described. In the following embodiments, the same components as those of the above-described embodiment will be denoted by the same reference numerals, and an overlapping description thereof may be omitted or simplified and differences will be mainly described.

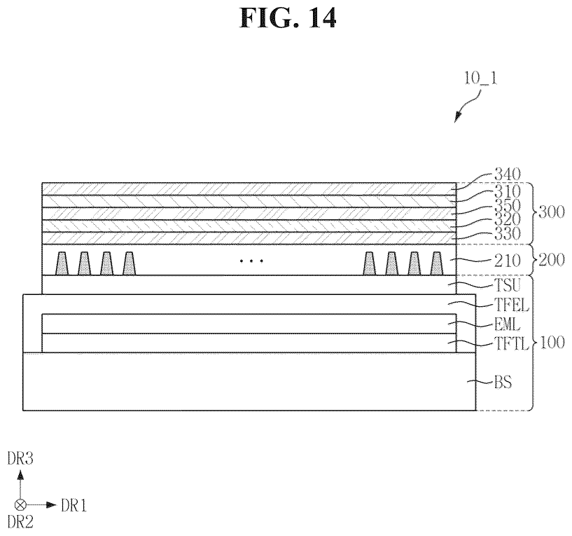

FIG. 14 is a cross-sectional view illustrating a display device according to an embodiment of the present disclosure.

Referring to FIG. 14, a display device 10_1 according to an embodiment of the present disclosure is different from the display device 10 according to an embodiment described with reference to FIG. 9 and the like in that the display device 10_1 does not include the base film layer 220.

For example, in an embodiment the light control film 200 may not include the base film layer 220. For example, the light control layer 210 of the light control film 200 may be in direct contact with the polarizing film 300 (e.g., in the direction opposite to the third direction DR3).

In the display device 10_1 according to an embodiment of the present disclosure, the birefringence of the light control film 200 may be minimized as the base film layer 220 is removed. Accordingly, external light reflectance may be reduced.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a display panel;
a light control film disposed above the display panel, the light control film including:
a light control layer including a light transmission pattern and a light blocking pattern disposed alternately with each other in a horizontal direction, and
a base film layer disposed on the light control layer; and
a polarizing film disposed above the light control film, the polarizing film including a phase retardation layer, a first protective layer, a polarizing layer, and a second protective layer.

2. The display device of claim 1, wherein the light control film is disposed directly between the display panel and the polarizing film.

3. The display device of claim 1, wherein the first protective layer and the second protective layer is disposed on a first side of the light control film, and
the display panel is disposed on a second side of the light control film, which the second side is an opposite side of the first side.

4. The display device of claim 1, wherein an ultraviolet transmittance of the base film layer is greater than an ultraviolet transmittance of the first protective layer and the second protective layer.

5. The display device of claim 4, wherein the first protective layer and the second protective layer include an ultraviolet absorber.

6. The display device of claim 1, wherein a birefringence of the light control film is less than or equal to about 0.03.

7. The display device of claim 1, wherein an SCI reflectance of the display device is less than or equal to about 5.5%.

8. The display device of claim 1, wherein the base film layer includes tri-acetyl cellulous (TAC).

9. The display device of claim 8, wherein the first protective layer and the second protective layer include tri-acetyl cellulous (TAC).

10. A display device comprising:
a display panel;
a light control film disposed above the display panel, the light control film including:
a light control layer including a light transmission pattern and a light blocking pattern disposed alternately with each other in a horizontal direction, and
a base film layer disposed on the light control layer; and
a polarizing film disposed above the light control film, the polarizing film including a phase adjustment layer and a polarization protective layer disposed on the phase adjustment layer.

11. The display device of claim 10, wherein the light control film is disposed directly between the display panel and the polarizing film.

12. The display device of claim 10, wherein the polarization protective layer is disposed on a first side of the light control film, and
the display panel is disposed on a second side of the light control film, which the second side is an opposite side of the first side.

13. The display device of claim 10, wherein an ultraviolet transmittance of the base film layer is greater than an ultraviolet transmittance of the polarization protective layer.

14. The display device of claim 13, wherein the polarization protective layer includes an ultraviolet absorber.

15. The display device of claim 10, wherein a birefringence of the light control film is less than or equal to about 0.03.

16. The display device of claim 10, wherein an SCI reflectance of the display device is less than or equal to about 5.5%.

17. The display device of claim 10, wherein the base film layer includes tri-acetyl cellulous (TAC).

18. The display device of claim 17, wherein the polarization protective layer includes tri-acetyl cellulous (TAC).

19. A display device comprising:
a display panel;
a light control film disposed above the display panel, the light control film including a light control layer including a light transmission pattern and a light blocking pattern disposed alternately with each other in a horizontal direction; and
a polarizing film disposed above the light control film, the polarizing film including a phase retardation layer, a first protective layer, a polarizing layer, and a second protective layer,
wherein the light control layer is in direct contact with the polarizing film, and
a birefringence of the light control film is less than or equal to about 0.03.

20. The display device of claim 19, wherein an SCI reflectance of the display device is less than or equal to about 5.5%.
